(19) United States
(12) Patent Application Publication
(10) Pub. No.: US 2009/0039464 A1
(43) Pub. Date: Feb. 12, 2009

(54) SEMICONDUCTOR DEVICE

(75) Inventors: Tetsuya Arai, Chuo-ku (JP); Kazuya Nojima, Higashimurayama (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/170,159

(22) Filed: Jul. 9, 2008

(30) Foreign Application Priority Data
Jul. 10, 2007 (JP) 2007-180800

(51) Int. Cl. H01L 23/525

(52) U.S. Cl. 257/529; 257/E23.149

(57) ABSTRACT

To protect an internal circuit against ESD breakdown which is caused by exposure of a cut-off portion of a fuse, a separate ESD protection circuit is not provided for each fuse as before, but the internal circuit is efficiently protected by a small number of ESD protection circuits by connecting the ESD protection circuit to a pad arranged for each unit lattice which is set in correspondence with a portion shared by a plurality of fuses, for example, a common wiring connected to the plurality of fuses, and which is set in correspondence with a size of a contact surface of a charged jig, or the like, with a semiconductor chip.

### BACKGROUND OF THE INVENTION

1. Field of the Invention

The present invention relates to a semiconductor device having a fuse used to relieve a semiconductor chip in which a failure is generated, and more particularly to a semiconductor device which is capable of suppressing electrostatic discharge (ESD) breakdown caused by exposure of a cut-off portion of the fuse.

2. Description of the Related Art

In a manufacturing process of a semiconductor device, the semiconductor device may become defective by ESD breakdown. The ESD breakdown of a semiconductor chip is caused in such a way that a high voltage pulse is made to flow into a circuit in the semiconductor chip due to a discharge of electric charges from an electrostatically charged object to a portion in which a conductive body of the semiconductor chip is exposed.

Therefore, there is ordinarily adopted a method for preventing the ESD breakdown in such a way that in addition to the circuit in the semiconductor chip, a path for flowing the high voltage pulse is provided by connecting a dedicated ESD protection circuit to the exposed portion of the conductive body, such as a pad, of the semiconductor chip.

Further, a semiconductor device including a memory, such as a DRAM, is subjected to processing for relieving a semiconductor chip having a defect generated therein, in which processing a defective memory cell is specified by performing inspection at the time when the manufacture of the semiconductor chip is completed, and the specified defective memory cell is then replaced with a redundant memory cell formed beforehand on the same semiconductor chip. In recent years, the manufacturing yield of semiconductor devices has been lowered according to the miniaturization of the memory cell. Further, there has been an increase in the ratio at which the memory cells are made defective by the stress applied in the burn-in test and the like, which is performed after the memory is assembled. Therefore, it is necessary to provide a relief method for coping with such problems.

As a method for relieving a semiconductor chip having a defect generated therein, there is used a technique (fuse blow) in which a plurality of fuses are provided on the semiconductor chip, and in which a specific fuse is cut by a laser beam so as to thereby operate a circuit necessary for replacing the defective chip with a redundant memory cell. The fuse is generally formed of a metal, such as aluminum (Al), and is covered by an insulating film in a non-cut-off state.

In the fuse blow using the laser beam, the insulating film covering the fuse surface is also exfoliated by the impact caused by the melt-down of the fuse, and hence the cut-off portion of the fuse is exposed after the fuse blow. As a result, when the semiconductor chip subjected to the fuse blow is assembled into a package, electric charges charged in an assembling jig (a collet, and the like) which is used in the assembling process, are discharged to the exposed cut-off portion of the fuse, so that ESD breakdown is caused in the circuit in the semiconductor chip.

As a preventive measure of ESD breakdown due to exposure of the cut-off portion of the fuse, there is disclosed, for example, in Japanese Patent Laid-Open No. 2006-73937 (hereinafter referred to as Patent Document 1) a configuration in which an ESD protection circuit is provided in each circuit connected to the fuse in the semiconductor chip.

In the following, the configuration and operation of the conventional semiconductor device as described in Patent Document 1 will be described with reference to the drawings.

FIG. 1A is a plan view showing a configuration of a conventional semiconductor device, and FIG. 1B is a circuit diagram showing the configuration of the semiconductor device. FIG. 1A shows an arrangement relation between fuses 102 and respective circuits arranged around the fuses. FIG. 1B schematically shows a connection relation between two fuses 102, internal circuits 105, common wiring 101, potential generation circuit 106, and ESD protection circuits 104. Note that in FIG. 1A and FIG. 1B, respective components are denoted by the same reference numerals.

As shown in FIG. 1A and FIG. 1B, plurality of fuses 102 to be cut are connected to common wiring 101. A fixed voltage generated in potential generation circuit 106 is supplied to respective fuses 102 via common wiring 101. Further, internal circuit 105, which is operated according to a non-cut-off state or a cut-off state of corresponding fuse 102, is connected to the end portion of each fuse 2 to which end portion common wiring 101 is not connected.

In the conventional semiconductor device, separate ESD protection circuit 104 is connected to each of plurality of internal circuits 105 and potential generation circuit 106. That is, ESD protection circuits 104 are provided as many as the number of fuses 102 and common wiring 101. Opening portion 103 is provided above fuses 102, and a thin insulating film is formed in opening portion 103 so as to make fuse 102 easily cut by a laser beam. An insulating film thicker than that of opening portion 103 is formed on the surface of common wiring 101, fuse 102, internal circuit 105, potential generation circuit 106, and ESD protection circuit 104 except the surface of opening portion 103. In such configuration, fuse 102 is covered by the thin insulating film even in opening portion 103, and thereby non-cut-off fuse 102 is not exposed.

On the other hand, when fuse 102 is cut by a laser beam, the cut portion of fuse 102 is exposed as described above. However, the charges discharged to the cut-off portion from the electrostatically charged jig, or the like, are made to flow into the ground potential, or the like, through ESD protection circuit 104 before reaching to internal circuit 105 and potential generation circuit 106. Thereby, the ESD breakdown of internal circuit 105 and potential generation circuit 106 can be suppressed.

However, in the conventional semiconductor device as described above, the ESD protection circuits need to be provided as many as the number of the fuses and the common wiring, and hence a large layout area is needed in order to arrange the ESD protection circuits in a semiconductor chip.

For example, in the case where hundreds of fuses are provided in a semiconductor device in order to relieve a memory in which a defect is generated, hundreds of ESD protection circuits need to be provided when a separate ESD protection circuit is connected for each of the fuses.

Further, usually, the plurality of internal circuits respectively connected to the fuses are very densely arranged. Thus, when the ESD protection circuits are provided as in the conventional semiconductor device, the layout design of the internal circuit becomes difficult. Further, the layout area of the ESD protection circuit is also restricted, and hence only an ESD protection circuit having a simple configuration can be used. This may result in a case where the internal circuit cannot be sufficiently protected against ESD breakdown.

### SUMMARY OF THE INVENTION

Thus, an object of the present invention is to provide a semiconductor device which is capable of sufficiently protecting the internal circuit against ESD breakdown, while reducing the number of the ESD protection circuits.

In order to achieve the above described object, according to the present invention, there is provided a semiconductor device including:

a plurality of fuses which are used to relieve a semiconductor chip having a defect generated therein, and the surface of which is covered by an insulating film; and

an ESD protection circuit which is connected only to a common circuit shared by the plurality of fuses, and which prevents electrostatic discharge breakdown of an internal circuit connected to the fuse, which breakdown is caused by exposure of a cut-off portion of the fuse.

Alternatively, according to the present invention, there is provided a semiconductor device including:

a plurality of fuses which are used to relieve a semiconductor chip having a defect generated therein and are formed close to the surface of the semiconductor chip, and the surface of which is covered by an insulating film;

a plurality of opening portions provided for each of a predetermined number of the fuses;

an ESD protection circuit which has an input terminal connected to a pad, and which prevents electrostatic discharge breakdown of an internal circuit connected to the fuse, which breakdown is caused by exposure of a cut-off portion of the fuse; and

the pad which has an exposed surface and is set in correspondence with a size of a contact surface of a charged object with the semiconductor chip, and which is arranged for a unit lattice including the plurality of opening portions, and for each of a plurality of unit lattices arranged adjacent to the unit lattice, and is connected to the input terminal of the ESD protection circuit.

With the above described configuration, one ESD protection circuit is connected to a common wiring shared by the plurality of fuses, or one ESD protection circuit is connected to the pads each of which is arranged for the each unit lattice. Thereby, the plurality of internal circuits can be protected against ESD breakdown by the one ESD protection circuit, and hence the number of ESD protection circuits can be reduced.

Further, the ESD protection circuit is connected only to the common wiring shared by the plurality of fuses or is connected only to the pads each of which is arranged for each of the unit lattices. Thus, the ESD protection circuit can be arranged so as to avoid the internal circuits which are densely arranged. Thereby, the restriction imposed on the layout area of the ESD protection circuit is reduced, so that a circuit configuration which is capable of sufficiently protecting the internal circuit against ESD breakdown can be used as the ESD protection circuit.

The above and other objects, features, and advantages of the present invention will become apparent from the following description with reference to the accompanying drawings, which illustrate examples of the present invention.

### BRIEF DESCRIPTION OF THE DRAWINGS

FIG. 1A is a plan view showing a configuration of a conventional semiconductor device;

FIG. 1B is a circuit diagram showing the configuration of the conventional semiconductor device;

FIG. 2A is a plan view showing a configuration of a first embodiment of a semiconductor device according to the present invention;

FIG. 2B is a circuit diagram showing the configuration of the first embodiment of the semiconductor device according to the present invention;

FIG. 3A is a sectional side view showing a state where the fuse shown in FIG. 2A and FIG. 2B is cut;

FIG. 3B is a plan view showing the state where the fuse shown in FIG. 2A and FIG. 2B is cut;

FIG. 4 is a plan view showing a configuration of a second embodiment of a semiconductor device according to the present invention;

FIG. 5 is a plan view showing a configuration of a third embodiment of a semiconductor device according to the present invention;

FIG. 6A is a sectional side view showing a configuration of a fifth embodiment of a semiconductor device according to the present invention;

FIG. 6B is a plan view showing the configuration of the fifth embodiment of the semiconductor device according to the present invention;

FIG. 7A is a sectional side view showing a configuration of a sixth embodiment of a semiconductor device according to the present invention; and

FIG. 7B is a plan view showing the configuration of the sixth embodiment of the semiconductor device according to the present invention.

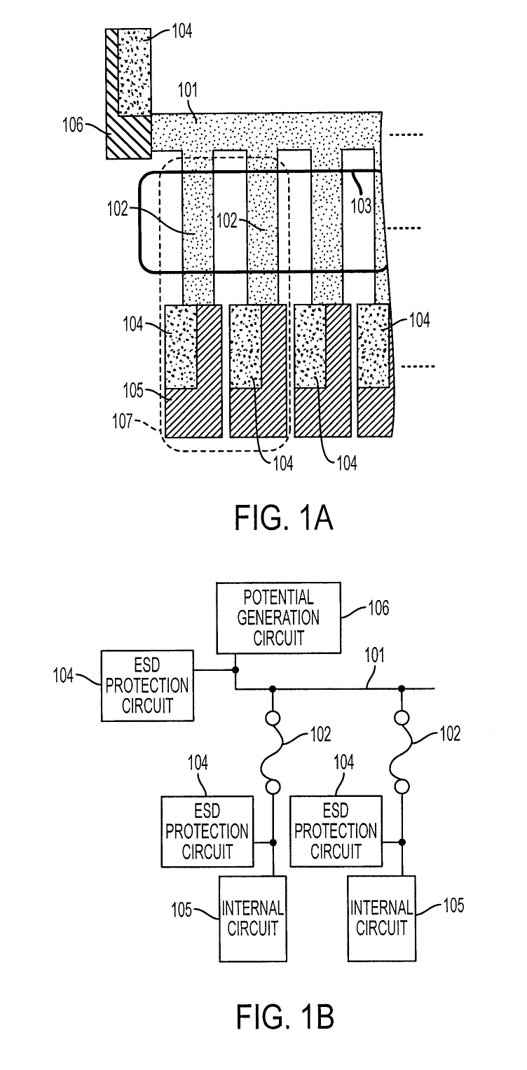

### DETAILED DESCRIPTION OF THE PREFERRED EMBODIMENTS

In the following, the present invention will be described with reference to the accompanying drawings.

In order to protect an internal circuit against ESD breakdown caused by exposure of a cut-off portion of a fuse, a semiconductor device according to the present invention is not configured such that a separate ESD protection circuit is provided for each of a plurality of fuses as in the conventional case, but is configured such that the ESD protection circuit is connected to a portion shared by the plurality of fuses and thereby the internal circuit is effectively protected by a small number of the ESD protection circuits.

### First Embodiment

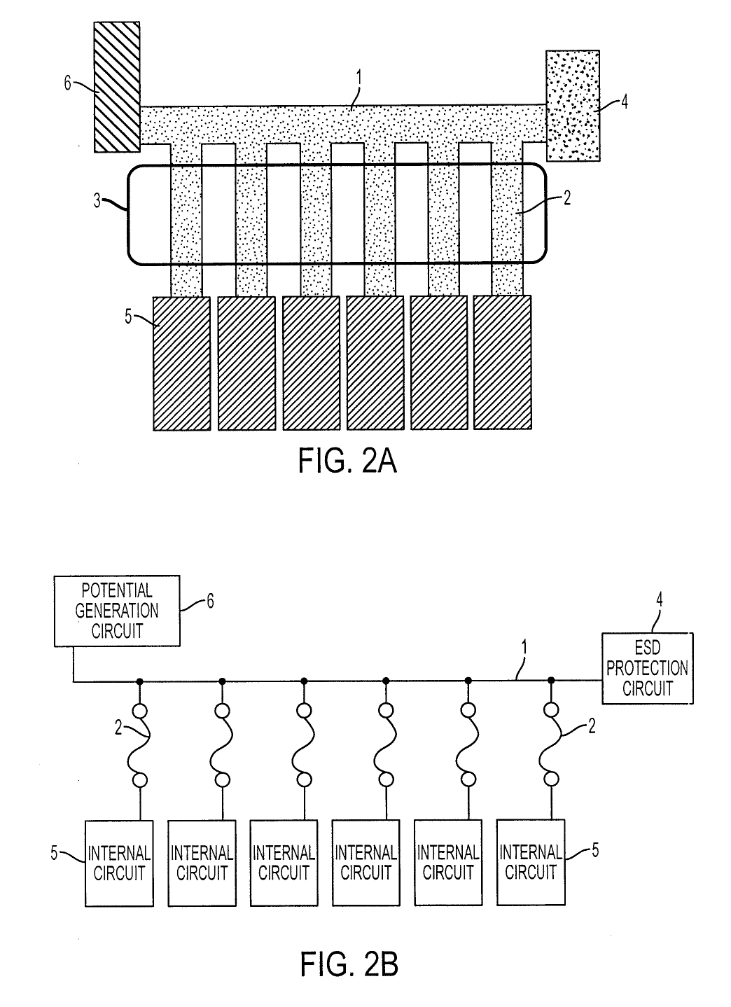

FIG. 2A is a plan view showing a configuration of a first embodiment of a semiconductor device according to the present invention. FIG. 2B is a circuit diagram showing the configuration of the first embodiment of the semiconductor device according to the present invention. FIG. 2A shows an arrangement relation between six fuses 2 and respective circuits arranged around the fuses. Further, FIG. 2B schematically shows a connection relation between fuses 2, internal circuits 5, common wiring 1, potential generation circuit 6, and ESD protection circuit 4 which are shown in FIG. 2A. In FIG. 2A and FIG. 2B, in order to prevent the drawings from becoming complicated, there is shown a configuration example provided with six fuses 2, but the number of fuses 2 is not limited to six. Normally, the semiconductor device includes much more number of fuses 2. Note that in FIG. 2A and FIG. 2B, respective components are denoted by the same reference numerals.

As shown in FIG. 2A and FIG. 2B, plurality of fuses 2 serving as objects to be cut are connected to common wiring 1, and a fixed voltage generated in potential generation circuit 6 is supplied to each of fuses 2 via common wiring 1. Further, the end portion of each of fuses 2, to which end portion common wiring 1 is not connected, is connected with each of internal circuits 5 which are operated according to a non-cut-off state or a cut-off state of corresponding fuse 2.

In the semiconductor device according to the first embodiment, separate ESD protection circuit 4 is not connected to each of plurality of internal circuits 5 and potential generation circuit 6 as in the conventional semiconductor device, but ESD protection circuit 4 is connected only to the portion shared in these circuits. That is, in the semiconductor device according to the first embodiment, ESD protection circuit 4 is connected only to the end portion of common wiring 1, to which end portion potential generation circuit 6 is not connected.

Similarly to the conventional case, opening portion 3 is provided above fuses 2, and a thin insulating film is formed in opening portion 3 so that fuse 2 can be easily cut by a laser beam. Except opening portion 3, an insulating film thicker than the insulating film provided in opening portion 3 is formed on the surface of common wiring 1, fuses 2, internal circuits 5, potential generation circuit 6, and ESD protection circuit 4. With such configuration, fuse 2 is covered by the thin insulating film even in opening portion 3, and hence non-cut-off fuse 2 is not exposed.

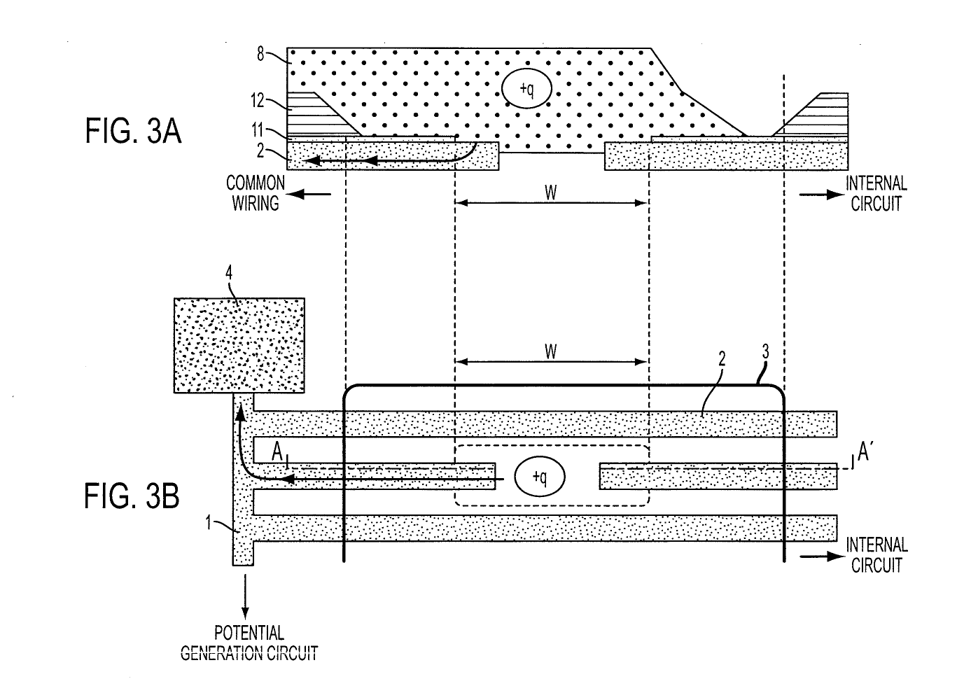

Next, an ESD protection operation of the semiconductor device according to present embodiment will be described with reference to FIG. 3A and FIG. 3B.

FIG. 3A is a sectional side view showing a state where a fuse shown in FIG. 2A and FIG. 2B is cut. FIG. 3B is a plan view showing the state where the fuse shown in FIG. 2A and FIG. 2B is cut. FIG. 3A shows a state of the cut surface obtained by cutting along the line A-A′ shown in FIG. 3B. Note that in FIG. 3A and FIG. 3B, respective components are denoted by the same reference numerals.

In the following, an ESD protection operation of the semiconductor device according to present embodiment will be described by taking, as an example, the case where one of plurality of fuses arranged in parallel with each other as shown in FIG. 3B, is cut by a laser beam, and where an assembling jig which is electrostatically charged is brought into contact with the exposed two cut-off portions of the fuse.

As shown in FIG. 3A, first insulating film 11 made of an oxide film, or the like, is formed on fuse 2. On first insulating film 11, there is formed second insulating film 12 which is made of an organic film, or the like, and which is thicker than first insulating film 11. Only first insulating film 11 is formed in opening portion 3 provided above fuses 2, and only first insulating film 11 covers the surface of fuses 2 in the state where fuses 2 are not cut.

When fuse 2 is cut by using a laser beam at the time of inspection of the semiconductor chip (the above described fuse blow), fuse 2 is separated into a first fuse connected to internal circuit 5 and a second fuse connected to common wiring 1, and the two cut-off portions are exposed. For example, electrostatically charged assembling jig 8, which becomes a cause of ESD breakdown, is brought into contact with each of the two cut-off portions, because the size of assembling jig 8 is larger than interval w between the two cut-off portions.

As shown in FIG. 3A, when assembling jig 8 is brought into contact with the cut-off portions of fuse 2 in the case where the semiconductor chip subjected to the fuse blow is sealed into a package, the electric charge (+q) discharged from charged jig 8 to the two cut-off portions is made to flow into the first fuse which is cut to have a smaller resistance and which is connected to ESD protection circuit 4. Then, the electric charge is made to flow into ESD protection circuit 4 through common wiring 1, without being made to flow in the direction of internal circuit 5 and potential generation circuit 6.

Normally, as ESD protection circuit 4, there is used a circuit having an input impedance sufficiently smaller than an input impedance of internal circuit 5 and an input impedance seen from the output side of potential generation circuit 6. Therefore, the charge (+q) discharged to the cut-off portion of fuse 2 from electrostatically charged jig 8 is made to flow into the ground potential, and the like, through ESD protection circuit 4, before reaching internal circuit 5 and potential generation circuit 6, so that ESD breakdown is prevented from being generated in internal circuit 5 and potential generation circuit 6.

In the semiconductor device according to the present invention, the configuration of ESD protection circuit 4 is not limited in particular. Thus, any circuit having an input impedance sufficiently smaller than the input impedance of internal circuit 5 and the input impedance seen from the output side of potential generation circuit 6, may be used as ESD protection circuit 4. Specific configurations of the ESD protection circuit are described in, for example, the above described Patent Document 1, or Japanese Patent Laid-Open No. 2006-80411 and Japanese Patent Laid-Open No. 2006-80413.

According to the semiconductor device of the present embodiment, plurality of internal circuits 5 can be protected against ESD breakdown with one ESD protection circuit 4 by connecting ESD protection circuit 4 to common wiring 1 shared by plurality of fuses 2. Thus, the number of ESD protection circuits 4 can be reduced.

Further, ESD protection circuit 4 is connected only to common wiring 1 shared by plurality of fuses 2, and thereby ESD protection circuit 4 can be arranged while avoiding densely arranged internal circuits 5. As a result, the restriction imposed on the layout area of ESD protection circuit 4 is reduced, so that a circuit configuration capable of sufficiently protecting internal circuits 5 against ESD breakdown can be adopted as ESD protection circuit 4.

Therefore, it is possible to sufficiently protect internal circuit 5 against ESD breakdown, while reducing the number of ESD protection circuits 4.

### Second Embodiment

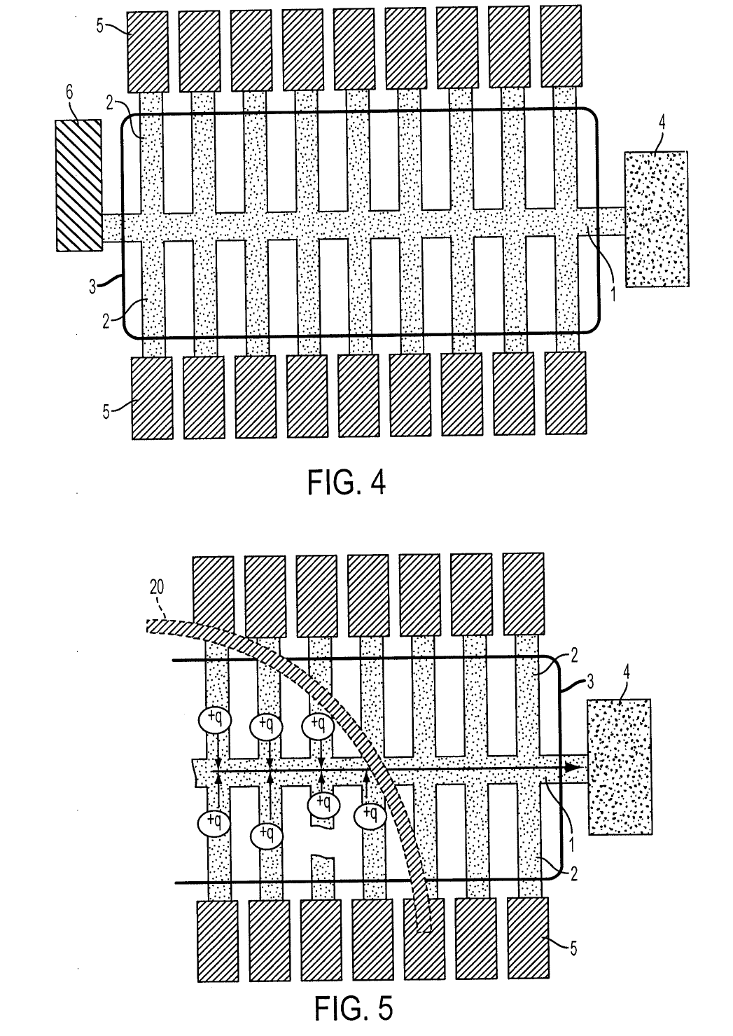

FIG. 4 is a plan view showing a configuration of a second embodiment of a semiconductor device according to the present invention.

The semiconductor device according to the second embodiment is configured such that in order to increase the number of internal circuits 5 protected by one ESD protection circuit 4, plurality of fuses 2 are connected to common wiring 1 in a shape such as a backbone of a fish (fish-bone shape). Similarly to the first embodiment, ESD protection circuit 4 is connected to an end portion of common wiring 1, to which end portion potential generation circuit 6 is not connected. FIG. 4 shows an example in which eighteen fuses 2 are connected to common wiring 1 in a fish-bone shape. The other configuration is the same as that of the semiconductor device according to the first embodiment, and hence the description thereof is omitted.

In the semiconductor device according to the second embodiment, plurality of fuses 2 are connected to common wiring 1 in the fish-bone shape, and thereby a number of fuses 2 can be arranged in a smallest layout area. ESD protection circuit 4 is connected to common wiring 1 to which a number of fuses 2 are connected, and thereby respective internal circuits 5 connected to common wiring 1 can be protected against ESD breakdown by the protective operation of ESD protection circuit 4, which operation is similar to that in the first embodiment.

According to the semiconductor device of the second embodiment, more internal circuits can be protected against ESD breakdown by one ESD protection circuit 4 as compared with the semiconductor device according to the first embodiment.

### Third Embodiment

FIG. 5 is a plan view showing a configuration of a third embodiment of a semiconductor device according to the present invention. Note that FIG. 5 shows a configuration example in which plurality of fuses 2 shown in the second embodiment are connected to common wiring 1 in a fish-bone shape.

The semiconductor device according to the third embodiment is configured such that an insulating film is not formed in opening portion 3 provided above plurality of fuses 2 and all fuses 2 are exposed in opening portion 3. Such configuration can be realized by performing etching processing, or the like, until the insulating film of opening portion 3 is completely eliminated. The other configuration is the same as that of the semiconductor device according to the second embodiment, and hence the description thereof is omitted.

In the semiconductor device according to the third embodiment, there is no insulating film in opening portion 3. Thus, when assembling jig 8 is brought into contact with the semiconductor chip subjected to the fuse blow, assembling jig 8 is brought into contact not only with the cut-off portion of fuse 2 but also with common wiring 1 and non-cut-off fuses 2.

For example, when assembling jig 8 is brought into contact with the semiconductor chip subjected to the fuse blow at contact surface 20 (hatched side) surrounded by the dotted line in FIG. 5, the charge is discharged from electrostatically charged jig 8 to all fuses 2 and common wiring 1 which exist within contact surface 20. Thereby, the charge discharged from jig 8 is made to flow into ESD protection circuit 4 through plurality of fuses 2 which have a small resistance and are arranged in parallel with each other, and through common wiring 1.

According to the semiconductor device of the third embodiment, the resistance of the discharge path, into which the charge discharged from jig 8, or the like, is made to flow, is reduced. Thus, the charge is made to flow from jig 8 into the discharge path of small resistance, so as to thereby prevent internal circuit 5 connected to fuse 2 in the cut-off state from being damaged. Therefore, internal circuit 5 and potential generation circuit 6 can be more surely protected against ESD breakdown.

Note that in the semiconductor device according to the present embodiment, the resistance of the discharge path is reduced as the number of fuses 2 brought into contact with jig 8 is increased, and hence the above described protection capability against ESD breakdown is also improved. Therefore, a larger effect can be obtained by the method for arranging fuses 2 in the fish-bone shape as shown in the second embodiment than in the method for arranging the fuses as shown in the first embodiment.

### Fourth Embodiment

In the semiconductor device according to the present invention, the material of fuse 2 is not limited in particular, but aluminum (Al) is generally used as the material of fuse 2. When fuse 2 and common wiring 1 are exposed similarly to the semiconductor device according to the third embodiment, internal circuit 5 and potential generation circuit 6 can be more surely protected against ESD breakdown, but the aluminum used for fuse 2 and common wiring 1 are liable to be corroded.

In the semiconductor device according to the fourth embodiment, fuse 2 to be exposed is made of a material having a lower ionization tendency and higher corrosion resistance than aluminum. Specifically, fuse 2 and common wiring 1 are formed of tungsten (W) or a material containing tungsten (for example, tungsten silicide (WSix)). The other configuration is the same as that of the third embodiment, and hence the description thereof is omitted.

When fuse 2 and common wiring 1 are formed of a material having higher corrosion resistance than aluminum as in the semiconductor device according to the present embodiment, it is possible to obtain the effect of suppressing the lowering of the corrosion resistance due to exposure of fuse 2 and common wiring 1, in addition to the same effect as that of the third embodiment.

### Fifth Embodiment

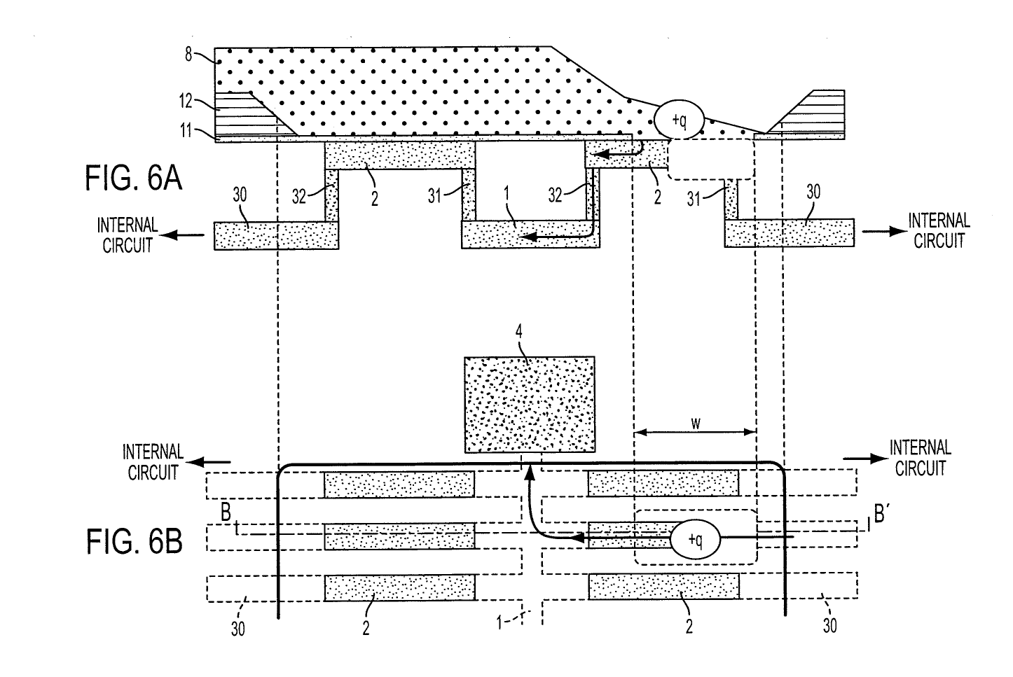

FIG. 6A is a sectional side view showing a configuration of a fifth embodiment of a semiconductor device according to the present invention. FIG. 6B is a plan view showing a configuration of the fifth embodiment of the semiconductor device according to the present invention. FIG. 6A shows a state of the cut surface obtained by cutting along the line B-B′ shown in FIG. 6B.

The semiconductor device according to the fifth embodiment is an example using, so-called, an island shaped fuse which is configured such that fuse 2 is formed close to the surface of the semiconductor substrate, and that respective wirings connected to fuse 2 are formed into wiring layers in the inside of the semiconductor chip from fuse 2. FIG. 6A and FIG. 6B show an example in which the island shaped fuses are arranged in the fish-bone shape as shown in the second embodiment. Note that in FIG. 6A and FIG. 6B, respective components are denoted by the same reference numerals.

As shown in FIG. 6A, fuse 2 is formed close to the surface of the semiconductor substrate, and relay wirings 30 which connect internal circuits 5 with common wiring 1 and fuse 2 are formed in the wiring layer in the inside of the semiconductor chip from fuse 2. Relay wiring 30 is connected with fuse 2 by first contact 31, and common wiring 1 is connected with fuse 2 by second contact 32.

As shown in FIG. 6A, first insulating film 11 made of an oxide film, or the like, is formed on fuse 2. Second insulating film 12, which is made of an organic film, or the like, and which is thicker than first insulating film 11, is formed on first insulating film 11. Only first insulating film 11 is formed in opening portion 3 provided above fuse 2. The surface of fuse 2 is covered by only first insulating film 11 when fuse 2 is not cut.

As shown in FIG. 6B, ESD protection circuit 4 is connected to the end portion of common wiring 1, to which end portion potential generation circuit 6 is not connected, similarly to the second embodiment. The other configuration is the same as that of the first embodiment and the second embodiment, and hence the description thereof is omitted.

In the semiconductor device according to the present embodiment, when fuse 2 is cut, the cutting process is performed by focusing a laser beam at the position of first contact 31 connected with relay wiring 30. When fuse 2 is cut at the position of first contact 31, fuse 2 on first contact 31 connected with relay wiring 30 is eliminated as shown in FIG. 6A, so that the cut-off portion of fuse 2 connected with second contact 32 and the upper surface of first contact 31 are exposed.

In this case, even when assembling jig 8 is brought into contact with the semiconductor chip subjected to the fuse blow, assembling jig 8 is sufficiently larger than width w between the cut-off portions of fuse 2, and is brought into flat contact with the exposed portion. Thus, assembling jig 8 is brought into contact with the cut-off portion of fuse 2 connected with second contact 32, but is not brought into contact with the upper surface of first contact 31. As a result, even when assembling jig 8 is charged, the charge discharged from assembling jig 8 is made to flow into second contact 32 and common wiring 1 from the cut-off portion of fuse 2 which is brought into contact with assembling jig 8, and is then made to flow into the ground potential, or the like, through ESD protection circuit 4 connected to common wiring 1.

According to the semiconductor device of the present embodiment, electrostatically charged jig 8 which may cause ESD breakdown is not brought into contact with first contact 31 connected with internal circuit 5, so that internal circuit 5 can be more surely protected against ESD breakdown.

### Sixth Embodiment

In the above described semiconductor devices according to the first embodiment to the fifth embodiment, there are shown examples in which one ESD protection circuit is arranged for one opening portion provided above a plurality of fuses. However, a semiconductor device according to a sixth embodiment is an example in which one ESD protection circuit is arranged for a plurality of opening portions. In this case, a fuse exposed in each of the opening portions is connected with the ESD protection circuit by using, for example, an assembling jig formed of a metal which is brought into contact with a semiconductor chip in the manufacturing process of the semiconductor device.

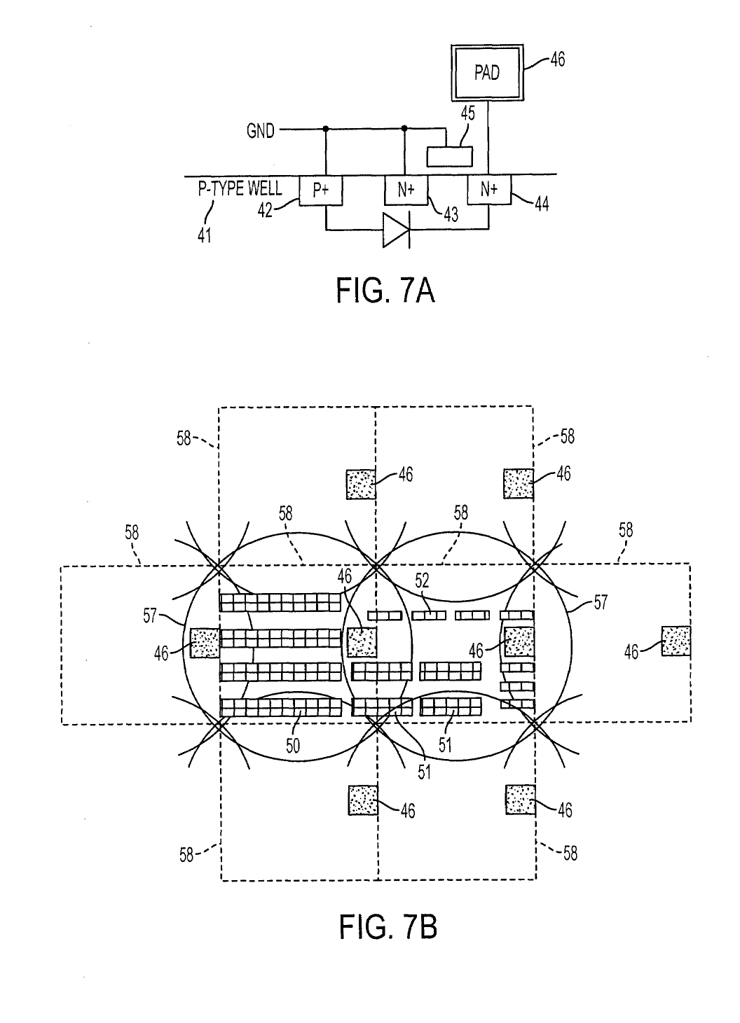

FIG. 7A is a sectional view showing a configuration of a sixth embodiment of a semiconductor device according to the present invention. FIG. 7B is a plan view showing the configuration of the sixth embodiment of the semiconductor device according to the present invention. FIG. 7A schematically shows a configuration example of an ESD protection circuit used in the present embodiment. FIG. 7B shows an arrangement example of the ESD protection circuit shown in FIG. 7A.

ESD protection circuit 4 used in the present embodiment is configured to include a diode connected NMOS transistor. As shown in FIG. 7A, the NMOS transistor is configured to include first N type diffusion layer 42 and second N type diffusion layer 43, which are formed in P-type well 41 of a semiconductor substrate so as to respectively serve as a source and a drain, and is also configured to include gate electrode 45 formed on first N type diffusion layer 43 and second N type diffusion layer 44 via an insulating film (not shown). Note that P type diffusion layer 42 shown in FIG. 7A is used to supply electric power to P-type well 41.

Gate electrode 45, P type diffusion layer 42, and first N type diffusion layer 43 are connected to the ground potential (GND), and second N type diffusion layer 44 is connected to exposed pad 46.

In the configuration shown in FIG. 7A, a PN junction diode is configured by P-type well 41 and second N type diffusion layer 44, so that second N type diffusion layer 44 serves as an input terminal of the diode, and P type diffusion layer 42 serves as an output terminal of the diode. Therefore, the configuration shown in FIG. 7A is capable of operating as ESD protection circuit 4 having a discharge path which enables the charge inputted from pad 46 to be released to the ground potential through P type diffusion layer 42 and first N type diffusion layer 43.

Note that FIG. 7A shows a configuration example of ESD protection circuit 4, and hence it is also possible to use other circuit configuration as ESD protection circuit 4.

In the present embodiment, there is shown an example of a method by which ESD protection circuit 4 shown in FIG. 7A is arranged in the semiconductor chip having a plurality of opening portions as shown in FIG. 7B. Note that FIG. 7B shows an example in which four first opening portions 50, four second opening portions 51, and seven third opening portions 52 are provided in the semiconductor chip.

For example, in the case where the contact surface of jig 8 which is brought into contact with the semiconductor chip has a circular shape, in order to protect internal circuit 5 in the semiconductor chip by ESD protection circuit 4 even at the time when jig 8 is brought into contact with any position of the semiconductor chip, pads 46 of ESD protection circuit 4 shown in FIG. 7A may be arranged in each of unit lattices 58, which are set in such a manner that as shown in FIG. 7B, two square unit lattices 58 including first opening portion 50 to third opening portion 52 are inscribed in contact surfaces 57, and that six unit lattices 58 are adjacent to two unit lattices 58.

In the state where ESD protection circuit 4 is arranged for each of unit lattices 58 in this way, even when jig 8 is brought into contact with any position of the semiconductor chip including first opening portion 50 to third opening portion 52, exposed fuse 2 in each opening portion 3 is connected with ESD protection circuit 4 by jig 8. Thereby, the charge discharged from charged jig 8 is not made to flow into exposed fuse 2 in opening portion 3, but is made flow from pad 46 into the ground potential, or the like, through ESD protection circuit 4. That is, in the semiconductor device according to the present embodiment, pad 46 serves as a portion shared by plurality of fuses 2.

In the semiconductor device according to the first embodiment to the fifth embodiment, one ESD protection circuit 4 is arranged for one opening portion 3 provided above a plurality of fuses. Thus, fifteen ESD protection circuits 4 are needed in the case of the semiconductor chip shown in FIG. 7B. On the other hand, in the semiconductor device according to the present embodiment, only eight ESD protection circuits 4 are needed. In the semiconductor device according to the present embodiment, ESD protection circuits 4 can be more efficiently arranged as the number of the opening portion is increased, and as opening portions 3 are arranged in a wider area.

According to the semiconductor device of the present embodiment, plurality of internal circuits 5 can be protected against ESD breakdown by one ESD protection circuit 4, and hence the number of ESD protection circuits 4 can be reduced. Further, ESD protection circuit 4 is connected only to pad 56 arranged for each unit lattice 58, and hence ESD protection circuit 4 can be arranged so as to avoid densely arranged internal circuits 5. Thereby, the restriction imposed on the layout area of ESD protection circuit 4 is reduced, and hence a circuit configuration capable of sufficiently protecting internal circuit 5 against ESD breakdown can be used as ESD protection circuit 4. Therefore, it becomes possible to protect internal circuit 5 against ESD breakdown, while further reducing the number of ESD protection circuits 4.

Note that the semiconductor device according to the present invention may be configured by any combination of the first embodiment to the fifth embodiment as described above, for example, in such a manner that the island shaped fuses as shown in the fifth embodiment are arranged in the fish-bone shape as shown in the second embodiment, and that each fuse is formed of tungsten as shown in the fourth embodiment.

Further, the configuration which is shown in the first embodiment to the fifth embodiment and in which one ESD protection circuit is arranged for one opening portion 3, and the configuration which is shown in the sixth embodiment and in which one ESD protection circuit is arranged for each of a plurality of opening portions, may also be provided in a mixed state.

While the invention has been particularly shown and described with reference to exemplary embodiments thereof, the invention is not limited to these embodiments. It will be understood by those ordinarily skilled in the art that various changes in form and details may be made therein without departing from the spirit and scope of the present invention as defined by the claims.

What is claimed is:

1. A semiconductor device comprising:
a plurality of fuses which are used to relieve a semiconductor chip having a defect generated therein, and the surface of which is covered by an insulating film; and
an ESD protection circuit which is connected only to a common wiring shared by the plurality of fuses, and which prevents electrostatic discharge breakdown of an internal circuit connected to the fuse, which breakdown is caused by exposure of a cut-off portion of the fuse.

2. The semiconductor device according to claim 1, wherein the plurality of fuses are connected to the common wiring in a fish-bone shape.

3. The semiconductor device according to claim 1, further comprising an opening portion above the plurality of fuses,
wherein all the fuses are exposed in the opening portion.

4. The semiconductor device according to claim 3, wherein the fuse is formed of a material having higher corrosion resistance than aluminum.

5. The semiconductor device according to claim 4, wherein the fuse is formed of a material containing tungsten.

6. The semiconductor device according to claim 1, further comprising:
a relay wiring which connects the internal circuit with the fuse,
wherein the common wiring and the relay wiring are formed in a wiring layer in the inside of the semiconductor chip from the fuse.

7. The semiconductor device according to claim 1, further comprising:
a pad which has an exposed surface and is set in correspondence with a size of a contact surface of a charged object with the semiconductor chip, and which is arranged for a unit lattice including the plurality of opening portions, and for each of a plurality of unit lattices arranged adjacent to the unit lattice, and is connected to the input terminal of the ESD protection circuit.

8. A semiconductor device comprising:
a plurality of fuses which are used to relieve a semiconductor chip having a defect generated therein and are formed close to the surface of the semiconductor chip, and the surface of which is covered by an insulating film;
a plurality of opening portions provided for each of a predetermined number of the fuses;
an ESD protection circuit which has an input terminal connected to a pad, and which prevents electrostatic discharge breakdown of an internal circuit connected to the fuse, which breakdown is caused by exposure of a cut-off portion of the fuse; and
the pad which has an exposed surface and is set in correspondence with a size of a contact surface of a charged object with the semiconductor chip, and which is arranged for a unit lattice including the plurality of opening portions, and for each of a plurality of unit lattices arranged adjacent to the unit lattice, and is connected to the input terminal of the ESD protection circuit.
